(19) United States
(12) Patent Application Publication
(10) Pub. No.: US 2011/0273704 A1
(43) Pub. Date: Nov. 10, 2011

(54) Direct, Diffuse, and Total Radiation Sensor

(75) Inventor: George Burba, Lincoln, NE (US)

(73) Assignee: Li-Cor, Inc., Lincoln, NE (US)

(21) Appl. No.: 12/775,351

(22) Filed: May 6, 2010

Related U.S. Application Data
(63) Continuation of application No. PCT/US2010/033920, filed on May 6, 2010.

(51) Int. Cl. G01J 1/42; G01J 1/06; H01L 31/0232

(52) U.S. Cl. 356/222; 250/237 R

(57) ABSTRACT

A solar radiation detector comprises a shading element that casts a shadow over one of a number of sensors disposed about the shading element. The shading element and the sensors are spaced in relation to each other that the shadow cast by the shading element always falls on one of the sensors, completely shading that one sensor, while at the same time leaves at least another one of the sensor completely exposed to direct solar radiation. The completely shaded sensor measures substantially only diffuse solar radiation.

### BACKGROUND

The present invention relates to apparatus and related methods for measuring solar radiation, and in particular to measuring diffuse solar radiation.

Solar radiation reaches the earth along two paths, as direct radiation from the sun itself and as diffuse radiation. As solar radiation passes through the earth's atmosphere, some of it is absorbed or scattered by air molecules, water vapor, aerosols, and clouds. The solar radiation that passes through directly to the earth's surface is referred to as direct solar radiation. The radiation that has been scattered out of the direct beam reaches the earth after having been scattered by the atmospheric particulate matter and is referred to as diffuse solar radiation. The standard measurement of diffuse solar radiation is taken on a horizontal surface, and so diffuse solar radiation is also referred to in the field as diffuse horizontal radiation. Total radiation (or global radiation) is the sum of the diffuse horizontal radiation and direct radiation. The term irradiation and its various grammatical forms are also conventionally used, and are interchangeably used with the various grammatical forms of radiation in the following description of the present invention. It will be understood that radiation refers to solar radiation (solar irradiation), whether direct or diffuse.

It has become increasingly evident that diffuse radiation measurements are an important factor in estimating photosynthetic rates (photosynthetically active radiation, PAR), modeling carbon consumption and sequestration in ecosystems, estimating cloud cover which can be used in automated weather station installations, climate modeling, and so on. While it is easy to measure the combined total effect of direct and diffuse radiation, it is not so easy to measure the diffuse radiation component alone.

There are three kinds of sensor configurations that are currently employed to measure diffuse radiation.

Classical shadow band. In this approach, a narrow crescent-shaped strip of metal or other material called a “shadow band” is placed above radiation detector and oriented along the path of the sun's movement so that it constantly shades the radiation detector from the sun as it moves across the sky during the course of the day. This kind of sensor provides diffuse radiation measurements only and requires manual adjustment of the band every 1-5 days. A person needs to go into the field and adjust the shadow band periodically. Because of this, the classic shadow band sensor configuration is prone to human error and can be very high-maintenance if the device is located in a remote location.

Moving shadow band. This sensor configuration is a common variant of the classic shadow band sensor. In this method, a shadow band of some shape rotates around, or oscillates, over a radiation detector. The lowest reading (when the band blocks the sun from the detector) is considered to be the diffuse radiation reading and highest reading is considered to be the total radiation. The direct radiation is computed as a difference between total measured radiation and diffuse radiation. This method provides diffuse, direct and total radiation measurements, and thus represents an improvement over the classic shadow band. However, a moving shadow band sensor requires motor(s) and various other moving parts, which presents challenges for field maintenance, requires power, and makes such sensors more expensive. U.S. Pat. No. 6,849,842 discloses an example of a moving shadow band diffuse radiation sensor, and is incorporated herein by reference for all purposes.

Half-dome with shading pattern. In this kind of sensor, several detectors are positioned under a transparent dome. Portions of the dome are opaque and portions are transparent in such a way that one detector is always shaded and one is always sunlit. This method provides diffuse, direct and total radiation, and does not have moving parts. However, these devices tend to be expensive, requiring substantial amounts of power (up to 18 Watts with a heater) to keep condensation and snow off the dome and to operate, and often require relatively frequent manual cleaning of the plastic dome in order to obtain correct readings. U.S. Pat. No. 6,417,500 discloses an example of a half-dome type sensor device, and is incorporated herein by reference for all purposes.

### BRIEF SUMMARY

In accordance with embodiments of the present invention, a solar detection instrument comprises several to many radiation detectors placed around a shading pole (or other similar shading structure). In embodiments, the radiation detectors may be arranged around the shading pole in any kind of pattern, for example, circular, rectilinear, and in general any arbitrary pattern. The radiation detectors can be discrete and relatively large (e.g., separate radiation sensors), or can be very small and arranged in a nearly continuous pattern (e.g., an arrangement of pixel-sized detectors), or anything in between.

The radiation detectors may be positioned relative to the shading pole such that at least one of the detectors always shaded by the shading pole (i.e., exposed only to diffuse radiation) and at least another one is always sunlit (i.e., exposed to total solar radiation including both direct solar radiation and diffuse solar radiation). As the sun moves across the sky, the shade cast by the shading pole will move, and so a different detector will become shaded and a previously shaded detector will become fully exposed to the sunlight. The detection instrument may include a data collection component which collects data from the detectors. The collected data can then be analyzed to produce various measures of solar radiation; e.g., direct, diffuse, and total radiation.

In embodiments, the solar detection instrument may employ detectors that provide measurements in a specific range or ranges of wavelengths.

With increasing evidence that diffuse radiation measurements are important in estimating photosynthetic rates and modeling carbon consumption and sequestration in ecosystems, embodiments of the present invention offer a low-cost low-maintenance devices that have a strong potential to become important and widely used alternative solution in flux and ecological networks that currently employ many thousands of conventional radiation sensors.

### BRIEF DESCRIPTION OF THE DRAWINGS

FIG. 1A illustrate an embodiment of a solar detection apparatus in accordance with the present invention.

FIG. 1B illustrates embodiments of a solar detection apparatus in accordance with an embodiment of the present invention having alternative shading structures.

FIG. 1C illustrates an embodiment of a solar detection apparatus in accordance with an embodiment of the present invention having an alternative shading structure.

FIG. 1D illustrates an embodiment of a solar detection apparatus in accordance with an embodiment of the present invention having an alternative construction of the base.

FIG. 1E is a photograph of an illustrative embodiment of the present invention constructed by the inventor.

FIGS. 2 and 3 show design parameters to facilitate construction of an embodiment of the present invention.

FIG. 4 shows an embodiment of the present invention that incorporates data collection.

FIG. 5 illustrates an aspect of the present invention for leveling.

FIG. 6 shows the incorporation of additional kinds of sensors.

FIGS. 7A-7E illustrate alternative arrangements of sensors.

FIGS. 8 and 9 illustrate comparative studies to assess the performance of an embodiment of the present invention.

FIG. 10 shows an embodiment of a computing apparatus in accordance with the present invention.

### DETAILED DESCRIPTION

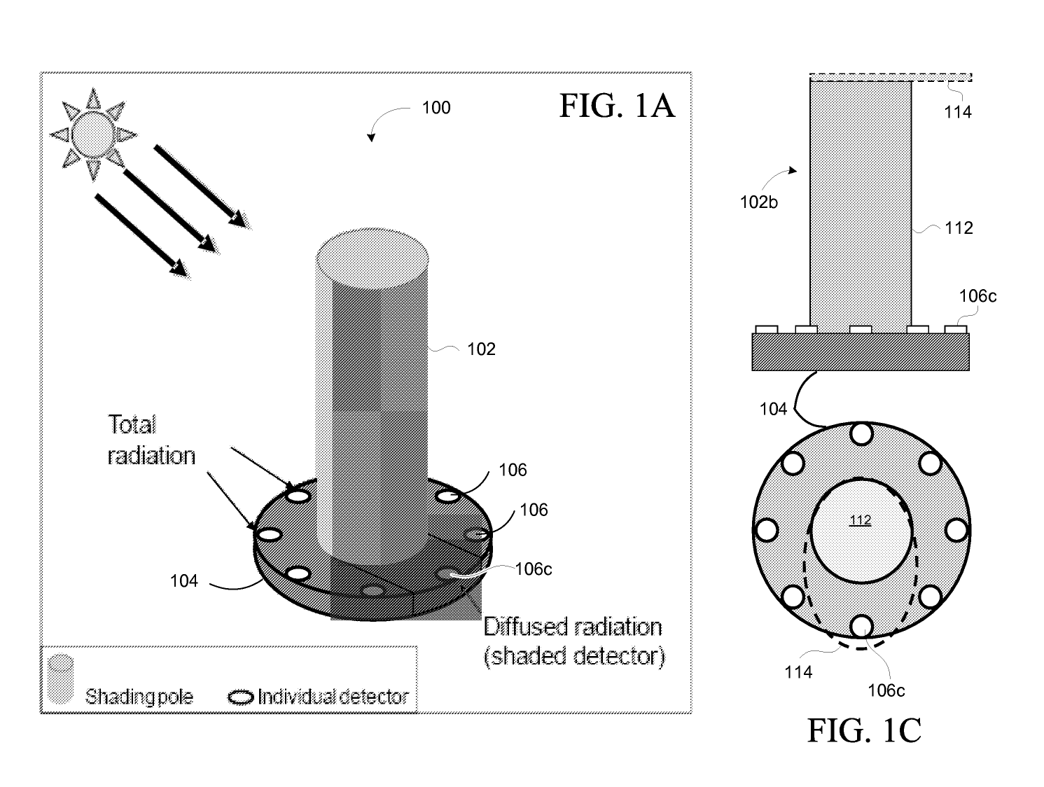

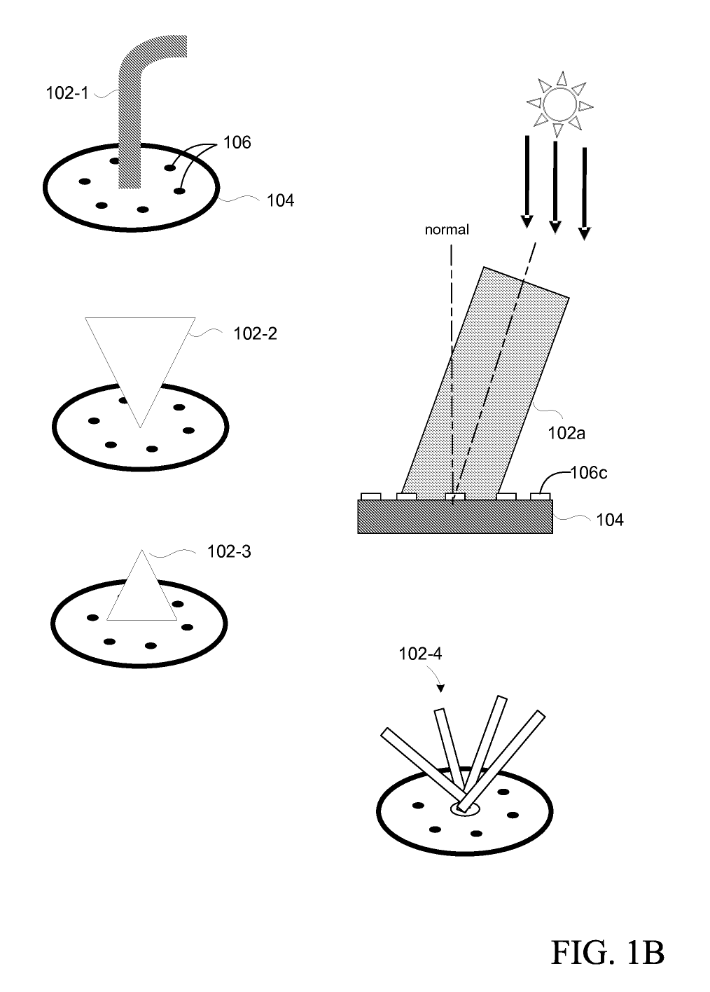

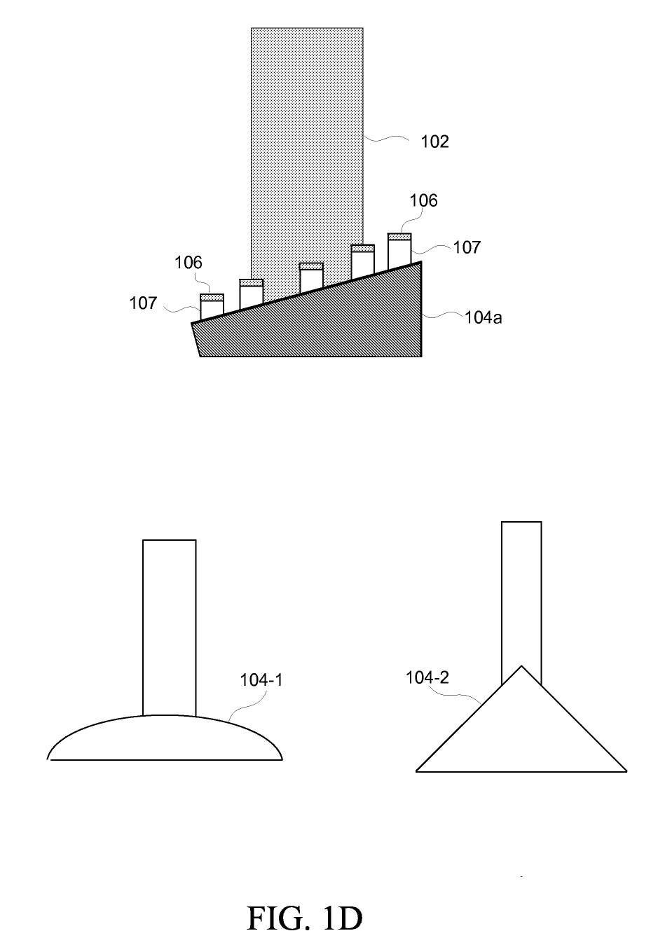

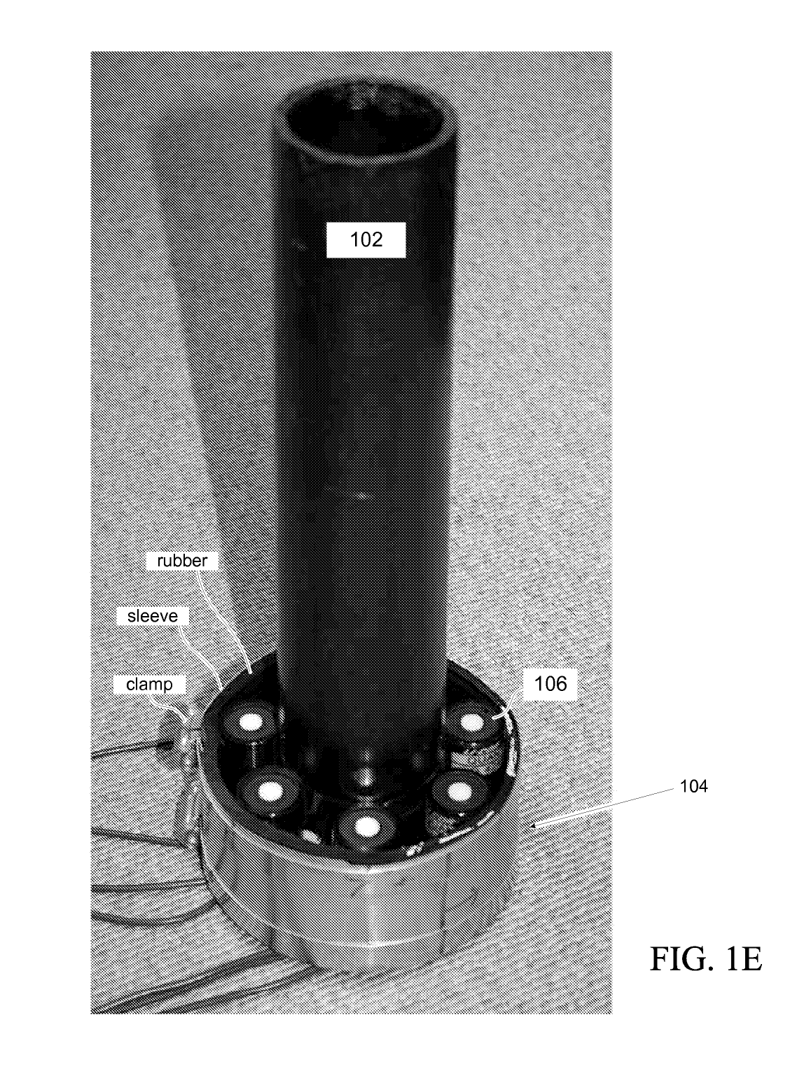

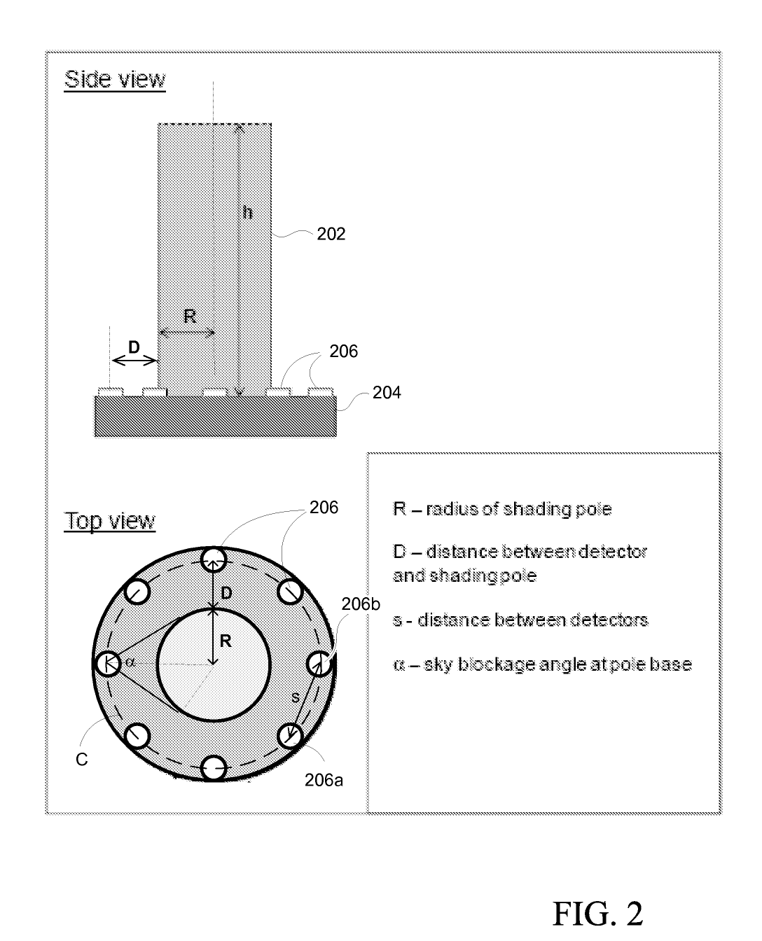

An embodiment of a solar detector 100 of the present invention, shown in FIG. 1A, comprises a shading structure 102 attached to a supporting base 104 to provide structure for supporting the shading structure and for supporting detectors 106. A plurality of detectors 106 may be disposed on an upper surface of the base 104, or otherwise supported by the base. This figure illustrates the general structure of embodiments of a solar detector in accordance with the present invention.

As can be seen in FIG. 1A, detectors 106a, 106b are completely exposed to total solar radiation, while detector 106c is completely shaded by the shading structure 102. As the sun moves, of course, so will the shadow that is cast by the shading structure 102. Consequently, detectors that were previously completely exposed to total solar radiation will become completely shaded, and previously completely shaded detectors will become completely exposed to total radiation. Of course, there will also be some detectors that are partially exposed/shaded by the shadow as the sun makes its slow progression across the sky. In accordance with the present invention, the shading structure 102 always casts a complete shadow over at least one of the detectors 106 while leaving at least another of the detectors is completely exposed to total radiation as the sun moves across the sky. This aspect of the invention will be discussed in further detail below.

In embodiments of the present invention, the shading structure 102 may comprise any suitable material that casts a shadow by occluding or otherwise blocking direct sunlight (direct solar radiation). In an embodiment, for example, a tube was initially fashioned out of pliable opaque card stock, and in a subsequent embodiment PVC piping was used. FIG. 1A shows that the shading structure 102 can be a vertical member having a cylindrical shape. However, it will be appreciated that other shapes may be equally suitable. In an embodiment, the material for the shading structure 102 might preferably be a more structurally durable material, such as plastic (e.g., PVC) or metal.

It will be appreciated that the shading structure 102 can take on other shapes. The shading structure 102 can have a square- or rectangular-shaped cross section, instead of a circular cross section as in the case of a cylindrical structure. The cross section can be V-shaped. Referring to FIG. 1B, the shading structure in an embodiment can be a curved structure 102-1. In an embodiment, the shading structure can be a conically shaped structure, such as the conical structure 102-2 or inverted conical structure 102-3.

In embodiments, the base 104 can be any suitable structure to which the shading structure 102 can be attached. The shading structure 102 may be detachably connected to the base 104 to allow for convenience in assembly, disassembly, and transport. FIG. 1A shows that the shading structure 102 may be mounted along a line that is substantially normal to the surface of the base 104. Such an embodiment is suitable for most of the time and in most regions in the world because even with the sun at its highest point in the sky at high noon, the sun is not directly overhead, and so a shadow will always be cast by the shading structure 102 with properly spaced sensors.

However in certain regions of the world, the sun can be just above the solar detector 100. For example such a situation occurs twice a year in the tropical and equatorial regions between the Tropic of Cancer and the Tropic of Capricorn. The sun's high position in the sky may require the shading structure 102 to be curved at the top or tilted at an angle to cast a shadow that sufficiently shades the detectors 106. Accordingly an embodiment, also shown FIG. 1B, may include a shading structure 102a that is oriented at an angle along a line away from the line normal to the surface of the base 104. The shading structure 102a casts a shadow over one of the detectors 106c even though the sun may be directly overhead. In alternate embodiment, also shown in FIG. 1B, the shading structure may further comprise a series of projecting elements 102-4 that extent to or beyond the perimeters of the detectors 106 to cast complete shadows over multiple detectors while at the same time leaving other detectors completely exposed to direct solar radiation as the sun moves across the sky.

In another embodiment (FIG. 1C) a shading structure 102b is shown comprising a vertical member 112 and an extension member 114. In an embodiment, the extension member 114 may be an elongate member of sufficient length to extend directly over one of the detectors 106c to ensure that the detector remains completely shaded even when the sun is directly overhead. This can be seen in the side- and top-views of the embodiment shown in FIG. 1C.

Returning to FIG. 1A, it will be appreciated that the detectors 106 should be un-occluded in order to ensure accurate detection of total and/or diffuse solar radiation. For example, it is desirable to avoid pooling of water around the light sensing component of the detector 106. Typically, detectors include a transparent dome that cover the light sensing components so that water does not collect on top, but rather runs off the sloped walls of the dome. The surface of the base 104 can be of a suitable material, texture, or structure that helps to prevent the accumulation and pile up of rainwater, snow, and/or debris on the base itself. In an embodiment, for example, a groove can be formed around each detector 106 to channel water away from the detector.

In an embodiment, illustrated in FIG. 1D, the surface of base 104a can be inclined to allow rainwater to run off and snow fall to slide off of the base. FIG. 1D also illustrates that the detectors 106 can be vertically spaced apart from the surface of the base 104a in order to reduce the likelihood of being occluded by debris that might accumulate on the base. For example, extension posts 107 can be provided. By placing the detectors 106 atop the post 107, they can remain relatively clear of any debris that may happen to fall upon the base 104a. In embodiments, the base can have other shapes such as a dome-shape base 104-1 or a triangular base 104-2, and so on.

An aspect of the present invention is that the shading structure 102 completely blocks direct solar radiation from (at least) one of the detectors 106 while at the same time leaving (at least) another one of the detectors completely exposed to total radiation when the solar detector device 100 is placed in the sunlight. Moreover, as the sun moves across the sky during the day, the detectors change from being completely exposed to total solar radiation, to being partially exposed (and partially blocked) from total radiation, to completely shaded from the direct solar radiation. Those detectors that are completely shaded from total radiation should be exposed only to diffuse solar radiation, and so the radiation measured by such a detector should represent only diffuse radiation.

In a particular embodiment of a solar detector according to the present invention, shown in FIG. 1E, a shading structure 102 (shading pole) may be formed from PVC, and may be about 60 mm in diameter and 280 mm in height. The base 104 can be fashioned from a heavy rubber layer inside of a metal sleeve and held together with a hose clamp. The base 104 supports 7 detectors 106 arranged around the shading pole 102. The detectors 106 were LI-190SB quantum sensors manufactured and sold by the assignee of the present invention. The detectors 106 may be spaced about 36 mm apart from each other, and about 13 mm away from the shading pole 102.

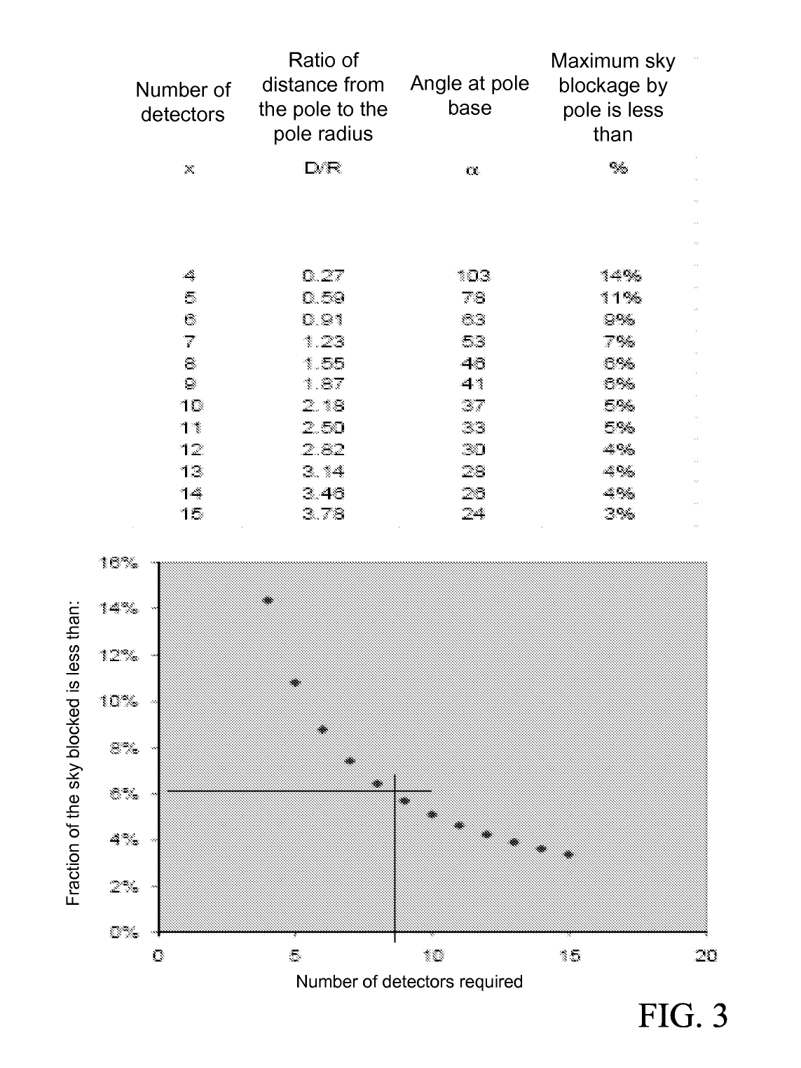

The discussion will now turn to an explanation of the design of an embodiment of a solar detector in accordance with the present invention. FIG. 2 illustrates top and side views of a solar detector 200 in accordance with an embodiment of the present invention. In the illustrated embodiment, the shading structure 202 is shown to be a cylindrical member having a width measurement represented in terms of its radius R and having a height measurement h. The height h of the shading structure 202 need only be sufficient to ensure that a shadow is cast over one of the detectors 206 when the sun is at its highest point in the sky. As explained in connection with FIGS. 1B and 1C, an additional shading member (114, FIG. 1C) may be required.

The placement of the detectors 206 relative to the shading structure 202 includes arranging the detectors around the shading structure and separated from the shading structure by a distance D (measured as the distance between the circumference of the shading structure to the center of the detector). The following analysis will assume that the design is driven by the R and D measurements; i.e., R and D are the design parameters.

A “sky blockage” angle, α, can be measured as the angle between two lines subtended from the center of the detector 206 to the outer perimeter of the shading structure 202. The sky blockage angle is set for a given R and D measurement, and can be determined as follows:

Equation 1 follows from basic trigonometric relations:

$$\frac{R}{R + D} = sin ( \frac{1}{2} α ) . \qquad ( Eqn . 1 )$$

Equation 2 results from an algebraic re-arrangement of Eqn. 1:

$$α = 2 arcsin ( \frac{1}{1 + \frac{D}{R}} ) . \qquad ( Eqn . 2 )$$

Eqn. 2 provides us with a relationship for determining the sky blockage angle, α, as a function of R and D.

Next, a discussion of will now be given for determining the minimum number of detectors x for a given design of R and D. Eqn. 3 is the formula for the circumference/of a circle C defined by the placement of the detectors 206 on the base 204, expressed in terms of R and D.

l=2π(R+D) (Eqn. 3).

The center-to-center distance between adjacent detectors 206a, 206b can be represented by the measurement s. Since the measurement s is a linear measurement between adjacent detectors 206a, 206b, the circumference/is approximately equal to s×x. Based on Eqn. 3, the separation measurement s, therefore, can be represented by the approximation:

$$s \approx \frac{2 π ( R + D )}{x} . \qquad ( Eqn . 4 )$$

Using Eqn. 4, the condition that will ensure that one of the detectors 206 will always fall completely within the shadow cast by the shading structure 202 can be expressed as:

s≦2R (Eqn. 5).

The reasoning is that the width of the shadow that falls on the base 204 is essentially equal to the width of the shading structure 202, namely 2R. Accordingly, if the spacing s of any two detectors 206 is less than 2R, then there will always be one detector that is completely shaded by the shading structure 202.

Combining Eqns. 4 and 5 and making some algebraic re-arrangement, we get:

$$2 R \geq \frac{2 π ( R + D )}{x} . \qquad ( Eqn . 6 )$$

Making a few more algebraic re-arrangements, we obtain an expression for the minimum number x of detectors, for the given R and D parameters, to ensure that at least one of the detectors will always fall inside of the shadow cast by the shading structure 202, namely:

$$x \geq π ( 1 + \frac{D}{R} ) . \qquad ( Eqn . 7 )$$

Recall that the foregoing analysis assumes that the design parameters are R and D. One of ordinary skill will readily appreciate that the design can be initiated with different combinations parameters as the starting point. For example, a similar analysis can be performed where the design begins with a requirement the we have, for example, eight detectors 206 (i.e., x=8) and the shading structure 202 has a width of W (i.e., R=½W). Also, depending on the diameter of the detector 206, R may be increased by one-half of such diameter, or more, to assure that there is no situation where two detectors are shaded partially and no detectors are shaded fully.

FIG. 3 shows a table of values for various configurations of R and D. The table shows how the number of detectors varies depending on R and D as the starting design parameters. The table also shows the sky blockage angle, α, for different combinations of R and D. The sky blockage angle in turn specifies the maximum percentage of the sky that can be blocked (referred to as “sky blockage percentage”) by the shadow when it falls on a detector. The maximum sky blockade can be determined as an angle at the base divided by 360.

FIG. 3 also shows a graph of how the number of detectors used for a given design of a solar detector 200 in accordance with the present invention affects the maximum fraction of sky that can be blocked from a detector 206 when it is completely overshadowed by the shading structure 202. Thus, the table can inform the user that, for a given number of detectors, the R and D measurements must satisfy a particular ratio and the graph can indicate what the expected maximum sky blockage percentage can be.

Conversely, the graph can be used to specify the design of a solar detector 200 in accordance with the present invention that satisfies a desired sky blockage criterion. Thus, if the user is interested in a detector that exhibits at most a sky blockage of 6% (for example), then the graph can be used (as shown in FIG. 3) to determine that the solar detector 200 will require about 9 detectors, possibly 10 to reduce the margin of error. The table can be consulted to determine that for a sky blockage of 6%, the R and D measurements of the solar detector must satisfy a D:R ratio of about 1.55 to 1.87.

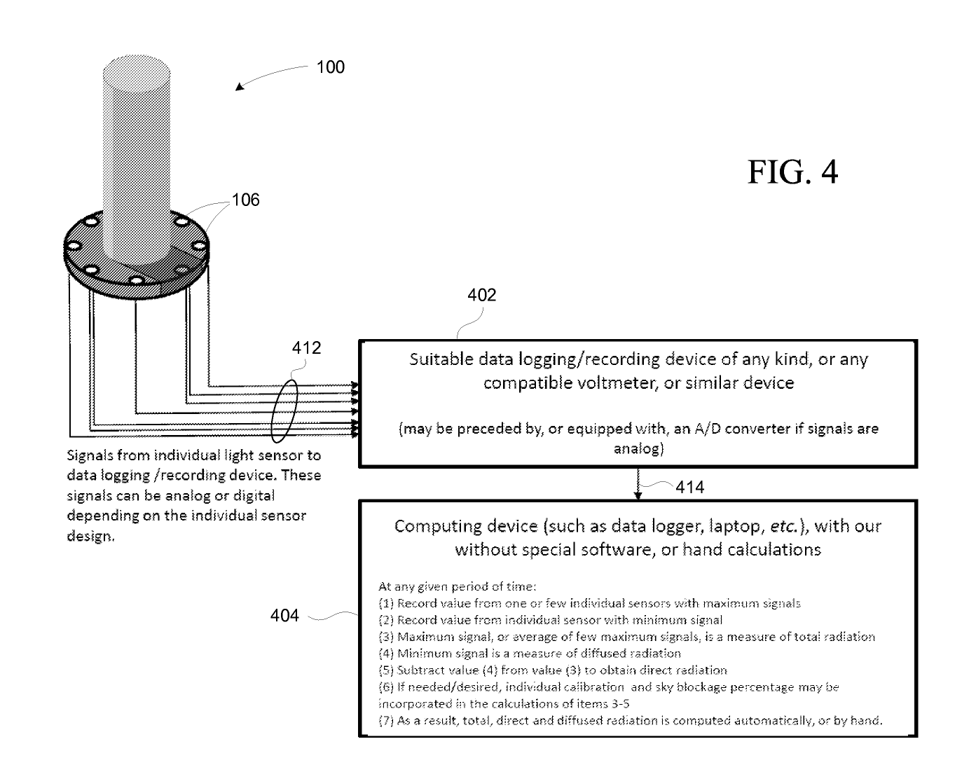

Referring now to FIG. 4, data collection in accordance with an embodiment of the present will be explained. The detectors 106 of a solar radiation detection instrument 100 in accordance with the present invention can be connected to a suitable data logger 402 over suitable signal lines 412. Measurements gathered by the detectors 106 can be conveyed to the data logger 402 via the signal lines 412. In an embodiment, the detectors 106 can be powered by a power source (e.g., battery, solar battery, etc., not shown) that is self-contained within the instrument 100 itself. In another embodiment, the detectors 106 can be powered via a power line (not shown) with power that originates from the data logger 402. In still another embodiment, the signal lines 412 themselves may carry power to the detectors 106.

In an embodiment, each detector 106 generates a continuous analog signal that varies with the radiation being detected at the moment. For example, the analog signal may simply be a voltage level. The analog signal can be coupled to suitable amplification circuitry and sampled by an A/D (analog/digital) converter, via the signal lines 412, contained in the data logger 402.

In another embodiment, more sophisticated detectors 106 may include circuitry that generate digital information indicative of the detected radiation. The digital information can be collected and stored by a suitable data logger 402.

In embodiments, the data logger 402 can store digital representations of the measurements provided by the detectors 106. The data logger 402 can include suitable data storage media for data collection. As just described, the detectors 106 may output continuous analog signals or a stream of digital readings which the data logger 402 collects. The data logger 402 can include a suitable computer interface 414 to allow a computer 404 to connect to it. The computer 404 can interact with the data logger 402 to collect the data and to perform certain data processing steps in accordance with the present invention. Commercially available data loggers include LI-400 DataLogger manufactured and sold by the assignee of the present invention. Data loggers from other vendors are available, such as the “CR” series of data loggers from Campbell Scientific. In general, any suitable data logger can be used.

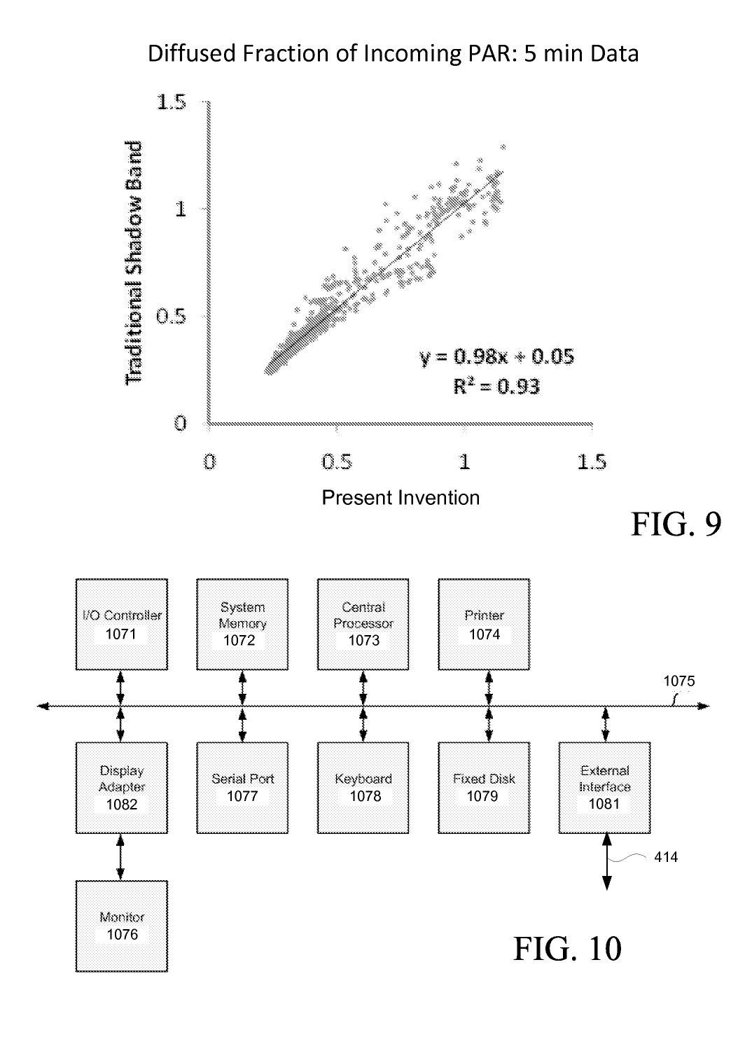

Referring for a moment to FIG. 10, an embodiment of the computer system 404 may include one or more of the subsystems or components shown in the figure, which is a block diagram of a computer apparatus. The subsystems shown in the figure are interconnected via a system bus 1075. Additional subsystems such as a printer 1074, keyboard 1078, fixed disk 1079, monitor 1076 coupled to display adapter 1082, and others are shown. Peripherals and input/output (I/O) devices, which couple to I/O controller 1071, can be connected to the computer system by any number of means known in the art, such as serial port 1077. For example, serial port 1077 or external interface 1081 can be used to connect the computer apparatus to a wide area network such as the Internet, a mouse input device, or a scanner. The data logger 402 can be connected via external interface 1081. The interconnection via system bus 1075 allows the central processor 1073 to communicate with each subsystem and to control the execution of instructions from system memory 1072 or the fixed disk 1079, as well as the exchange of information between subsystems. The system memory 1072 and/or the fixed disk 1079 may embody a computer readable medium.

Any of the software components or functions described in this application, may be implemented as software code to be executed by a processor using any suitable computer language such as, for example, Java, C++ or Perl using, for example, conventional or object-oriented techniques. The software code may be stored as a series of instructions, or commands on a computer readable medium, such as a random access memory (RAM), a read only memory (ROM), a magnetic medium such as a hard-drive or a floppy disk, or an optical medium such as a CD-ROM. Any such computer readable medium may reside on or within a single computational apparatus, and may be present on or within different computational apparatuses within a system or network.

In an embodiment, program instructions recorded on a computer readable storage medium may be provided that will cause the computer 404 to collect from the data logger 402 a set of signal readings for each period of time (collection step). For example, a set of readings may be collected every two minutes. A set of readings may comprise a reading from each detector 106 obtained by the data logger 402. For each set of readings collected for each period, certain processing can be performed.

A “maximum signal” value can be determined from among readings in the set of readings. In one embodiment, the maximum signal can simply be the reading having the greatest value. In another embodiment, one or more of the highest valued signals can be selected and then averaged to produce the “maximum signal” value. An example of “highest” might the two highest readings selected from among the readings in the set of readings. It will be appreciated that any suitable criterion can be used to define “highest.”

A “minimum signal” value can be determined from the among the readings in a set. In an embodiment, there may be only one or two detectors that are completely shaded by the shading structure 102 (of course, depending on the particular shading structure, more than two detectors may be completely shaded). Accordingly, there may only be one reading that is the minimum among the collected set of signal readings. Such minimum reading could constitute a “minimum signal” value.

The maximum signal value represents a measure of the total solar radiation (which includes direct solar radiation and diffuse solar radiation). Conversely, the minimum signal value represents a measure of diffuse solar radiation, only. Subtraction of the minimum signal value from the maximum signal value will produce a value that represents a measure of the direct solar radiation. The computation can be performed by the computer 404 and recorded along with the maximum and minimum signal values and stored for further processing.

In an embodiment, individual calibration and sky blockage percentage can be incorporated. The actual sky blockage, as opposed to maximum sky blockage (defined before), can be computed from a solid angle of the blocking shape in relation to a detector. Solid angle of the hemisphere is about 2π steradians. The solid angle of a specific blocking shape, in units of steradians, is a 2-dimensional area of this shape projected on a sphere, and divided by the squared distance between the blocking shape and detector. There are other ways to compute or measure the sky blockage. They are well known and lay beyond the scope of this invention.

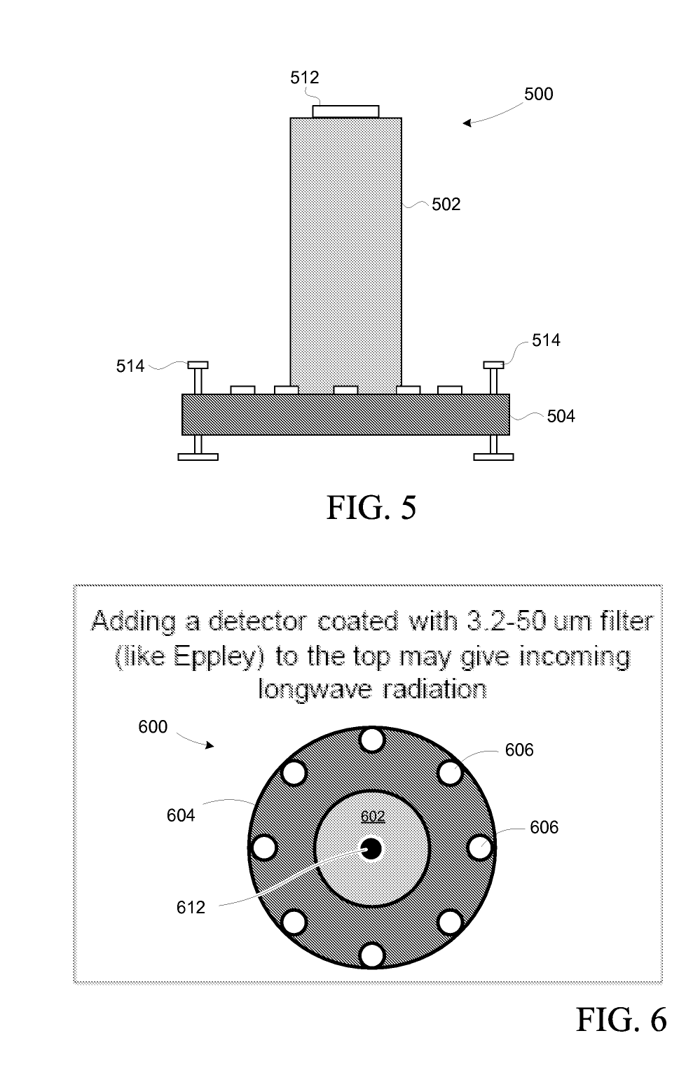

Referring now to FIG. 5, it was explained above that it is desirable to avoid the accumulation of water/snow or other occluding debris that can block both direct and diffuse solar radiation which would adversely impact the taking of proper solar radiation measurements. Another consideration is the proper location of a solar detector with respect to the surrounding landscape. For example, when making “above-canopy” measurements, a proper measurement of diffuse radiation requires detection only of diffuse solar radiation coming from the sky, not diffuse radiation reflected from the landscape or other structures (natural or otherwise) such as trees, leaves, buildings, and so on. Accordingly, solar detectors are typically situated in flat isolated areas whenever it is practical to do so. Also, it may be desirable that the solar detector be made level with respect to ground to avoid contaminating the measurements with diffuse radiation reflected from the landscape. It will be understood that the specific kind of measurement will dictate what constitutes proper conditions. For example, measurements made inside a plant canopy (such as made for photosynthesis studies) typically include diffuse radiation from reflections off of leaves, branches, and so on.

In an embodiment, a solar detector apparatus 500 may be provided with a built-in level 512 and adjustment legs 514. The level 512 can be mounted atop the shading structure 502 (shown), or on the side of the shading structure. The base 504 can be provided with a suitable number of adjustment legs 514 to facilitate leveling the apparatus 500.

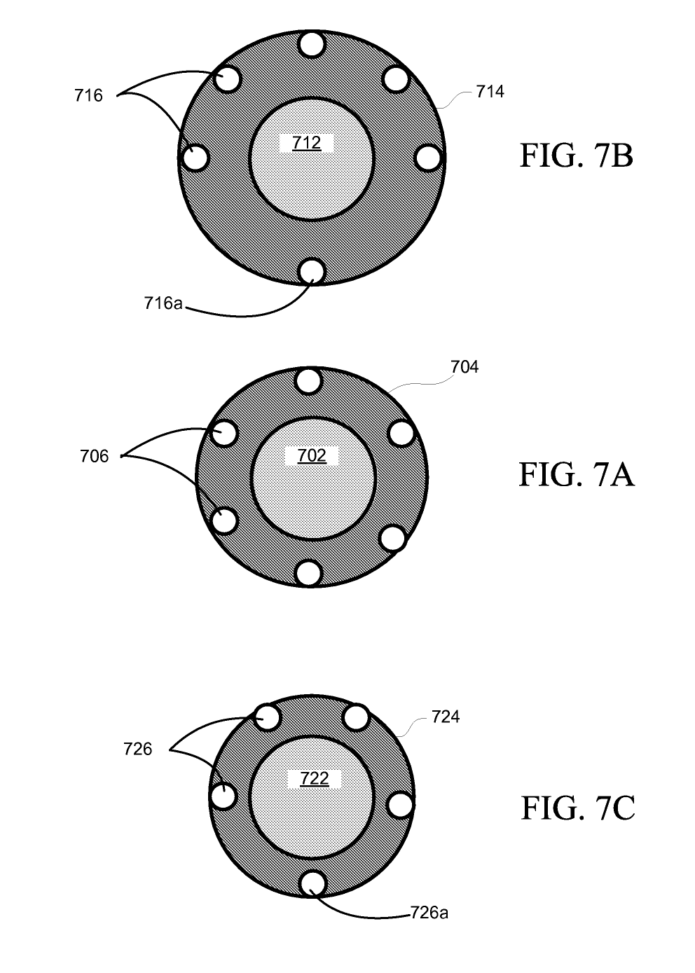

Referring to FIG. 6, a solar detection device 600 in accordance with the present invention may include one or more specialized detectors to sense portions of the spectrum not detected by the detectors 606, or in order to obtain more accurate readings of portions of the spectrum. The detectors 606 that are typically used for solar radiation measurements are not adequate for sensing the longer wavelengths in the micrometer range. However, a particular scientific study may call for measurements of wavelengths other than what is conventionally detected by a solar radiation detector. As an illustration, the solar detector 600 in FIG. 6 is shown having an additional sensor that is coated with a filter (e.g., Eppley) that can detect wavelengths in the 3.2-50 μm range. It can be appreciated that solar detectors of the present invention can be enhanced to provide addition detection capability.

Examples of commercially available detectors 606 used for solar radiation detection are known as pyranometer detectors. It will be appreciated of course that other kinds of detectors can be used. For example, “quantum” detectors can be used to measure direct PAR (photosynthetically active radiation), in addition to measuring total and diffuse solar radiation.

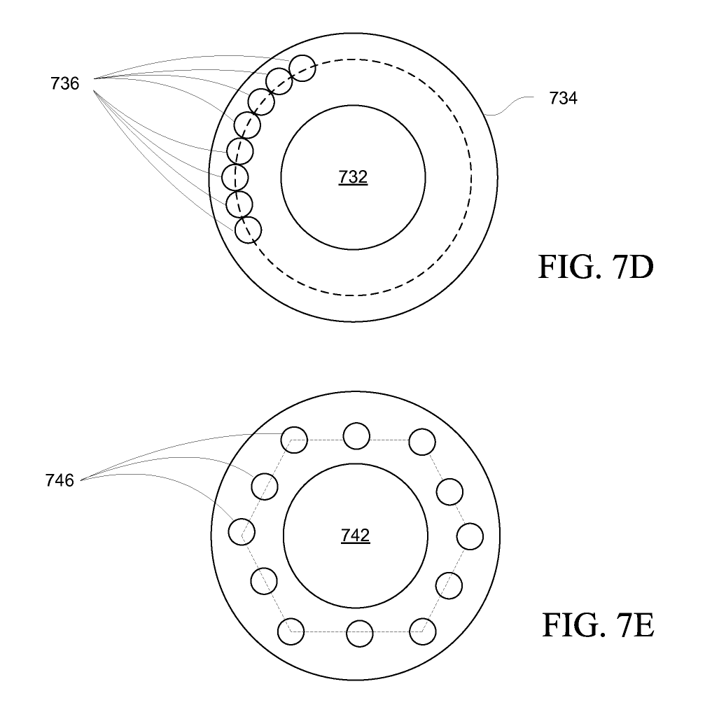

FIG. 7A shows an embodiment in which solar radiation sensing elements 702 disposed on a substrate 704 are evenly distributed about a shading element 702. As can be seen the embodiment shown in FIG. 7A, there are six solar radiation sensing elements 706 arranged about the shading element 702 in a circular fashion. FIGS. 7B and 7C illustrate alternative embodiments that use fewer sensing elements, and thus can achieve a lower-cost product. Each of the embodiments in FIGS. 7B and 7C will require special care in orientation of the instrument so that the “singled-out” detector (e.g., 716a or 726a) is facing away from the pole in respective hemisphere (north or south). By comparison, the embodiment of FIG. 7A implies easy installation in all geographic locations.

For example, in FIG. 7B an embodiment comprises six sensing elements 716, 716a. The sensing elements are disposed on the base 714, but are distributed around the shading element 712 in an uneven manner. In particular, the sensing elements 716 are biased toward one end of the base 714. This configuration of biasing the distribution of the sensing elements 716 provides for performance that is equivalent to having eight sensors that are evenly and symmetrically arranged around the shading pole. The embodiment shown in FIG. 7B can be a lower cost configuration, but may be less convenient to use because it requires accurate orientation.

The embodiment shown in FIG. 7C comprises five sensing elements 726, 726a arranged in a non-symmetric arrangement around the shading element 722. This configuration is similar to 7B, except the closer location of the detectors 726 to the pole leads to a fewer number of needed detectors. A less desirable consequence of the embodiment of FIG. 7C may be that there is greater sky blockage with this configuration.

In an embodiment shown in FIG. 7D, a plurality of sensing elements 736 can be arranged around the shading element 732 on the base 734 in a contiguous manner. The embodiment shown in the figure illustrates that the sensing elements 736 may be arranged around the shading element 732 in a circular arrangement, as indicated by the dashed line. However in another embodiment, the sensing elements can be arranged in a non-circular pattern. For example, FIG. 7E illustrates that an embodiment of the present invention may comprise sensing elements 746 arranged around the shading element 742 in a rectilinear fashion (e.g., a hexagonal pattern). It will be appreciated of course that in general the arrangement of sensing elements around the shading element may be any pattern.

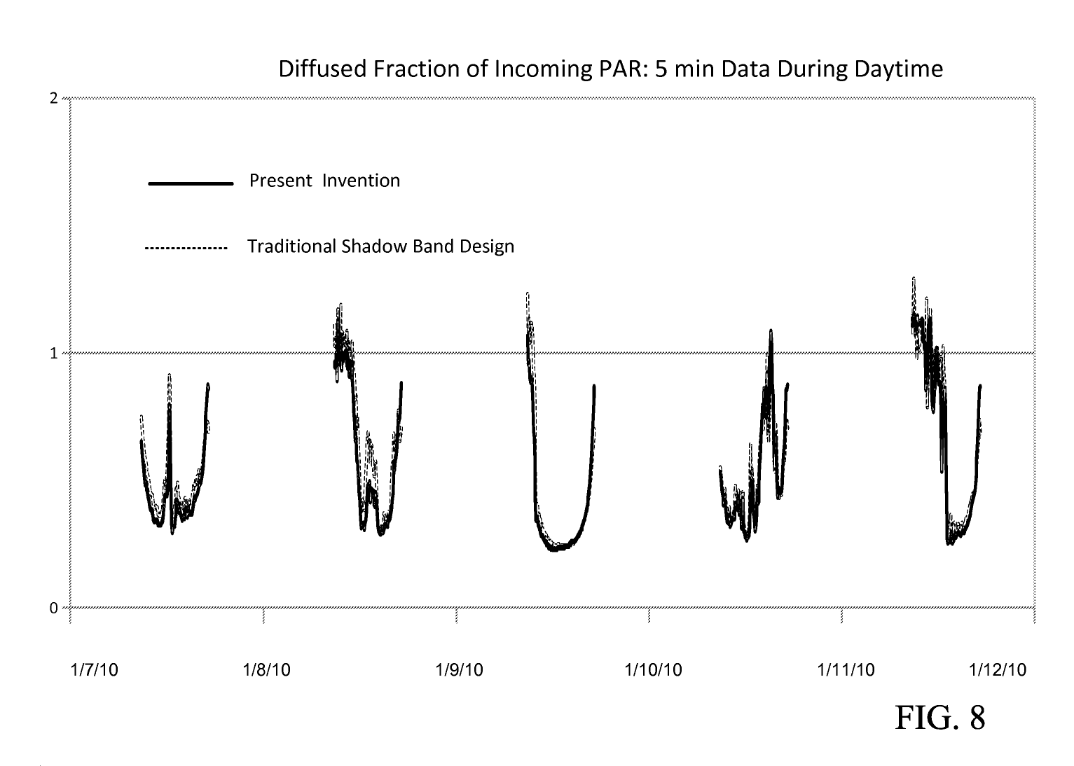

FIGS. 8 and 9 illustrate comparison graphs, comparing performance of a conventional solar radiation detection device against an embodiment of the present invention. In particular, conventional shadow band device was used as a representative of a conventional device. The embodiment illustrated in FIG. 1A was used as a representative embodiment of the present invention.

In FIG. 8, data was collected at five minute intervals during the daytime, for five days. The data represents diffused fraction of total radiation (Y-axis) as measured by a proposed invention and as measured by a standard shadow band design, plotted versus time (X-axis). Nighttime data are removed. This is to validate that proposed device measures the diffuse radiation correctly.

In FIG. 9, the diffused fraction of total radiation collected from the conventional device and from an embodiment of the present invention are compared to each other.

As can be seen from the data in FIGS. 8 and 9, the performance of a solar radiation detection device in accordance with the present invention compares favorably to conventional devices. However, embodiments in accordance with the present invention resolve deficiencies of conventional sensors without incurring any of their shortcomings. There is no need for a shadow band, moving parts, motors, manual maintenance, and no power is required. No manual cleaning is usually needed, similar to regular dome-less detectors. The price can be kept low. Diffused, direct and total radiation readings can be provided.

Embodiments of the present invention allow measuring diffused radiation, which is important for CO₂ and photosynthesis research, because CO₂ increases rates of photosynthesis by penetrating deeper into canopy. It is also important for monitoring cloud cover and used in numerous types of climate modeling.

What is claimed is:

1. A solar radiation sensor comprising:
a base;
a shading member attached to said base;
a plurality of detectors disposed on said base, said detectors arranged around said shading member,
wherein, as the sun moves across the sky, the shading member always completely occludes one of the detectors from the sun's direct solar radiation while at the same time leaving another one of the detectors completely exposed to the sun's direct solar radiation.

2. The sensor of claim 1 wherein said detectors are disposed symmetrically around said shading member.

3. The sensor of claim 1 wherein said detectors are disposed on a surface of said base.

4. The sensor of claim 3 wherein said surface of said base is sloped.

5. The sensor of claim 1 wherein said detectors are spaced apart from said shading member by a predetermined measure.

6. The sensor of claim 4 wherein the number of detectors is based on the predetermined measure of spacing of said detectors from said shading member.

7. The sensor of claim 6 wherein the number of detectors is further based on a width measurement of said shading member.

8. The sensor of claim 1 wherein said shading member comprises a vertical member having a protrusion extending outwardly therefrom.

9. The sensor of claim 1 wherein said shading member is vertically aligned substantially normal to said base.

10. The sensor of claim 1 wherein said shading member is tilted at an angle relative to a line normal to said base.

11. A method of measuring the sun's irradiation comprising:
supporting a vertical member relative to a surface that is exposed to the sun's radiation;
arranging a plurality of detectors around said vertical member, wherein a shadow cast by said vertical member completely blocks the sun's direct solar radiation from at least one of said detectors while at the same time leaving at least another one of said detectors completely exposed to the direct solar radiation, wherein the shadow is cast over different detectors depending on a location of the sun in the sky;
collecting information from each detector that is indicative of total radiation sensed by said each detector; and
determining a measurement of direct solar radiation based on information collected from at least a first detector and a second detector.

12. The method of claim 11 wherein said detectors are contiguous with each other in their arrangement around said vertical member.

13. The method of claim 11 wherein said information is digital information.

14. The method of claim 11 wherein said information is an analog signal, the method further comprising converting said analog signal to digital information.

15. The method of claim 11 further including spacing each detector apart from said vertical member by a predetermined distance.

16. A solar radiation detection apparatus comprising:
a base;
a shading structure attached to said base; and
a plurality of solar radiation sensors disposed on said base, said solar radiation sensors arranged around said shading structure,
wherein said solar radiation sensors are disposed in relation to said shading structure such that, when said apparatus is exposed to the sun, said shading structure always casts a shadow upon at least one of said solar radiation sensors while at the same time leaving at least another one of said solar radiation sensors completely exposed to the sun's direct solar radiation,
wherein said shadow is cast over different solar radiation sensors depending on the sun's location in the sky.

17. The apparatus of claim 16 wherein the number of said solar radiation sensors is determined based on a width measurement of said shading structure and a spacing of said solar radiation sensors from said shading structure.

18. The apparatus of claim 17 wherein the number of said solar radiation sensors is computed as
$$x \geq π ( 1 + \frac{D}{R} ) ,$$
where D is said spacing of said solar radiation sensors from said shading structure and R is one half of said width measurement of said shading structure.

19. The apparatus of claim 16 wherein said shading structure comprises a cylindrical member.

20. The apparatus of claim 19 wherein said shading structure further comprises at least one elongate member that extends beyond a perimeter of one of said solar radiation sensors.
